(19) United States
(12) Patent Application Publication
(10) Pub. No.: US 2009/0009937 A1
(43) Pub. Date: Jan. 8, 2009

(54) Electronic devices with storage compartments for memory devices

(76) Inventor: Brenda S. Jones, Raleigh, NC (US)

Correspondence Address: MYERS BIGEL SIBLEY & SAJOVEC, PO BOX 37428, RALEIGH, NC, 27627, US

(21) Appl. No.: 11/825,165

(22) Filed: Jul. 5, 2007

(51) Int. Cl. H05K 5/00

(52) U.S. Cl. 361/680; 361/681; 361/684

(57) ABSTRACT

An electronic device includes a housing having a top surface, a bottom surface, and a plurality of connecting surfaces that connect the top surface to the bottom surface. A display is mounted within the top surface and a keypad is mounted within the top surface adjacent the display. One or more storage compartments are located on one or more of the housing surfaces, and each storage compartment is configured to removably receive a memory device therein in non-operative relationship with the electronic device.

### FIELD OF THE INVENTION

The present invention relates generally to electronic devices and, more particularly, to electronic devices with storage compartments.

### BACKGROUND OF THE INVENTION

The use of promotional items has proliferated in today's. increasingly competitive marketplace, where companies are constantly seeking more effective and new ways to market their products. In the healthcare industry, physicians and other healthcare providers often receive promotional articles from vendors of healthcare-related products, such as pharmaceutical products. These promotional articles often include “everyday” items, such as writing pads, calendars, and pens that have promotional information (indicia) printed thereon. For example, pharmaceutical companies often provide physicians with writing pens having the name of a particular pharmaceutical product printed thereon with the hopes that the pens will help remind the physicians to prescribe the particular pharmaceutical product.

Unfortunately, because of lack of distinctiveness, many promotional articles provided to healthcare providers often become “lost-in-the-shuffle” with other promotional articles. Thus, there is a need for distinctive, more effective promotional products directed to healthcare providers as well as to providers of other products and services.

### SUMMARY

In view of the above discussion, electronic devices that serve as convenient storage compartments for one or more portable memory devices are provided. A memory device is not electrically coupled with an electronic device and does not communicate with the electronic device in any way. Electronic devices, according to embodiments of the present invention, provide a convenient and novel way of storing and transporting memory devices and are excellent promotional devices for a variety of product and service providers.

According to some embodiments of the present invention, an electronic device includes a housing having a top surface, a bottom surface, and a plurality of connecting surfaces that connect the top surface to the bottom surface. A display is mounted within the top surface and a keypad is mounted within the top surface adjacent the display. One or more storage compartments are located on one or more of the housing surfaces, and each storage compartment is configured to removably receive a memory device therein in non-operative relationship with the electronic device.

In some embodiments of the present invention, an ejector mechanism may be operably coupled with a storage compartment that is configured to eject a memory device from the storage compartment when activated by a user. In some embodiments of the present invention, at least one substrate with printed indicia thereon may be slidably secured within the housing and configured to move between a stored position within the housing and an exposed position extending outwardly from the housing.

According to other embodiments of the present invention, a combination electronic device and memory device is provided and includes a housing having a top surface, a bottom surface, and a plurality of connecting surfaces that connect the top surface to the bottom surface. A display is mounted within the top surface and a keypad is mounted within the top surface adjacent the display. One or more storage compartments may be provided in one or more of the housing surfaces. A memory device is removably received in one or more of the storage compartments in non-operative relationship with the electronic device. Each memory device has a USB connector and a protective cap covering the USB connector when stored within a storage compartment.

### BRIEF DESCRIPTION OF THE DRAWINGS

The accompanying drawings, which form a part of the specification, illustrate embodiments of the present invention. The drawings and description together serve to fully explain the invention.

FIG. 1 is plan view of an electronic device that stores memory devices, according to some embodiments of the present invention.

FIGS. 2-3 are partial perspective views of the electronic device of FIG. 1 illustrating a storage compartment for removably receiving a memory device therein.

FIGS. 4-5 are rear perspective views of the electronic device of FIG. 1 illustrating another storage compartment for removably receiving a memory device therein, according to other embodiments of the present invention.

FIGS. 6-7 are rear perspective views of the electronic device of FIG. 1 illustrating another storage compartment for removably receiving a memory device therein, according to other embodiments of the present invention.

FIG. 8 is a rear plan view of the electronic device of FIGS. 6-7.

FIGS. 9-10 are partial perspective views of the electronic device of FIG. 1 illustrating multiple storage compartments for removably receiving memory devices therein, according to other embodiments of the present invention.

FIGS. 11A-11B are perspective views of an electronic device that stores memory devices, according to other embodiments of the present invention.

FIGS. 12A-12B are perspective views of an electronic device that stores memory devices, according to other embodiments of the present invention.

FIGS. 13A-13B are perspective views of an electronic device that stores memory devices, according to other embodiments of the present invention.

FIGS. 14A-14B are perspective views of an electronic device that stores memory devices, according to other embodiments of the present invention.

### DETAILED DESCRIPTION

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like reference numbers signify like elements throughout the description of the figures.

As used herein, the singular forms “a,” “an,” and “the” are intended to include the plural forms as well, unless expressly stated otherwise. It should be further understood that the terms “comprises” and/or “comprising” when used in this specification are taken to specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the drawings, the thickness of lines, layers and regions may be exaggerated for clarity. It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of a device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of “over” and “under”. A device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a “first” element, component, region, layer or section discussed below could also be termed a “second” element, component, region, layer or section without departing from the teachings of the present invention.

Embodiments of the present invention provide electronic devices, including hand-held electronic devices and other portable electronic devices, that serve as convenient storage compartments for one or more portable memory devices. The memory devices are not electrically coupled with the electronic devices and do not communicate with the electronic device in any way. Electronic devices, according to embodiments of the present invention, provide a convenient and novel way of storing and transporting memory devices and are excellent promotional devices for a variety of product and service providers.

Electronic devices, according to embodiments of the present invention, may be any type of device including, but not limited to, calculators (e.g., medical calculator, finance calculator, etc.), personal data assistants (PDAs), laptop computers, etc. Moreover, any type of portable memory device may be stored within. electronic devices, according to embodiments of the present invention. As used herein, the term “memory device” means any type of portable memory device including, but not limited to, USB flash drives and other flash memory storage devices (e.g., Compact Flash® cards, Secure Digital® memory cards, Sony® memory sticks, SanDisk® memory sticks, Lexar® memory sticks, etc.). Memory devices utilized in accordance with embodiments of the present invention may have virtually any size memory.

As used herein, the terms “substantially flush” and “flush”, when used in reference to memory devices removably stored within storage compartments, mean that a plane defined by a memory device surface is relatively close to or aligned with a plane defined by the surface of an electronic device having a storage compartment therein. As such, the terms “substantially flush” and “flush” allow for some mismatch in the plane of a memory device surface and a plane defined by a housing surface. Thus, the terms “substantially flush” and “flush” describe a memory device that extends slightly outwardly from a storage compartment opening and a memory device that is slightly recessed within a storage compartment.

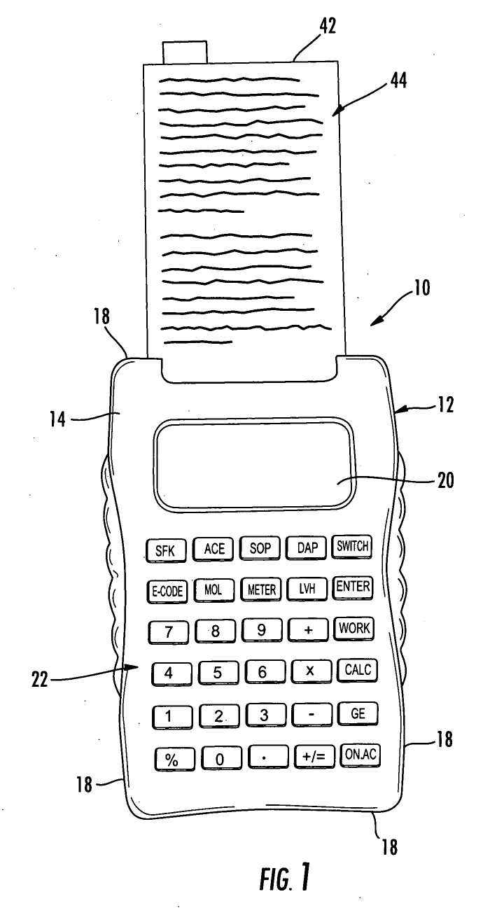

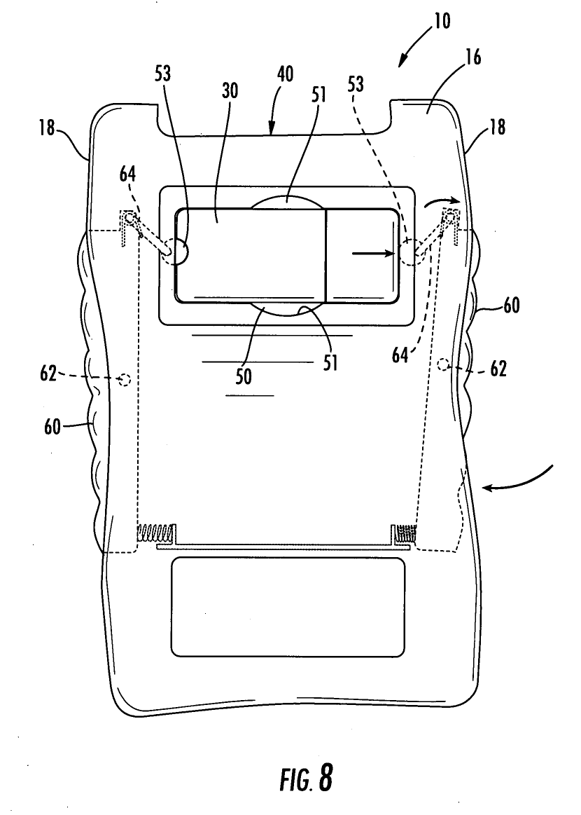

Referring initially to FIGS. 1-8, an electronic device 10 that stores memory devices 30 in non-operative relationship therewith, according to embodiments of the present invention, is illustrated. The electronic device includes a housing 12 having a top surface 14, a bottom surface 16, and a plurality of connecting surfaces 18 that connect the top surface 14 to the bottom surface 16. A display 20 is mounted within the top surface 14 and a keypad 22 is mounted within the top surface 14 adjacent to the display 20. A storage compartment 24 is located in a connecting surface 18 and is configured to removably receive a memory device 30 therein in non-operative relationship with the electronic device 10.

The term “non-operative relationship” means that there is no electrical connection or communication between the electronic device 10 and the memory device 30. The electronic device 10 provides a convenient, novel storage device for portable memory devices that may be used as a promotional item.

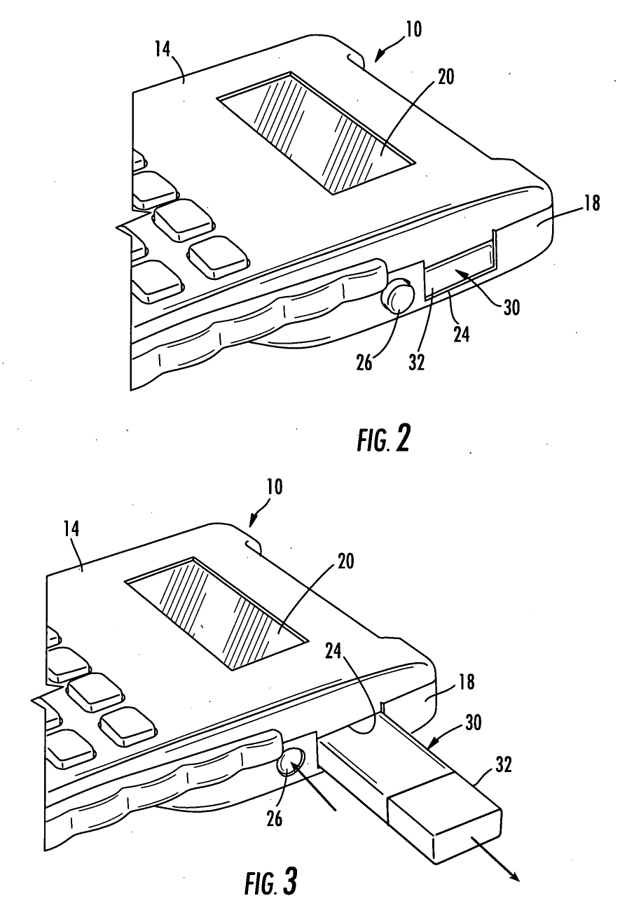

In the illustrated embodiment, the storage compartment 24 includes an ejector mechanism operably coupled therewith that is configured to eject a memory device 30 from the storage compartment 24. An actuator 26 extends from the housing surface 18 adjacent the storage compartment 24, as illustrated. FIG. 2 illustrates a memory device 30 stored within the storage compartment 24 and FIG. 3 illustrates the memory device 30 being ejected from the storage compartment 24 in response to a user pressing the actuator 26. Ejector devices that may be utilized within electronic devices according to embodiments of the present invention are well understood by those skilled in the art of electronic devices and need not be discussed further herein.

Embodiments of the present invention are not limited to storage compartments with ejector mechanisms. In other embodiments of the present invention, a storage compartment 24 may be configured to receive a memory device snugly therein (i.e., such that a friction fit is obtained) to allow the memory device to be stored therein, but also to allow easy removal by a user.

Still referring to FIGS. 2-3, the memory device 30 is stored entirely within the storage compartment 24 such that no portion of the memory device 30 extends from the housing 12. In the illustrated embodiment, the memory device 30 is substantially flush with the connecting surface 18. However, in other embodiments, storage compartment 24 may be configured such that a memory device 30 is not stored entirely therewithin, and some portion of the memory device 30 may extend from the storage compartment 24. For example, in embodiments where no ejector device is utilized, a portion of a memory device 30 will need to extend from a storage compartment to allow a user to grasp the memory device 30 and remove it from the storage compartment 24.

The illustrated memory device 30 is a USB flash device with a USB connector 31 (FIG. 5) and a protective cap 32 covering the USB connector 31. Storage of the memory device 30 with the cover 32 overlying the USB connector 31 further illustrates that the memory device 30 does not communicate in any way with the electronic device 10.

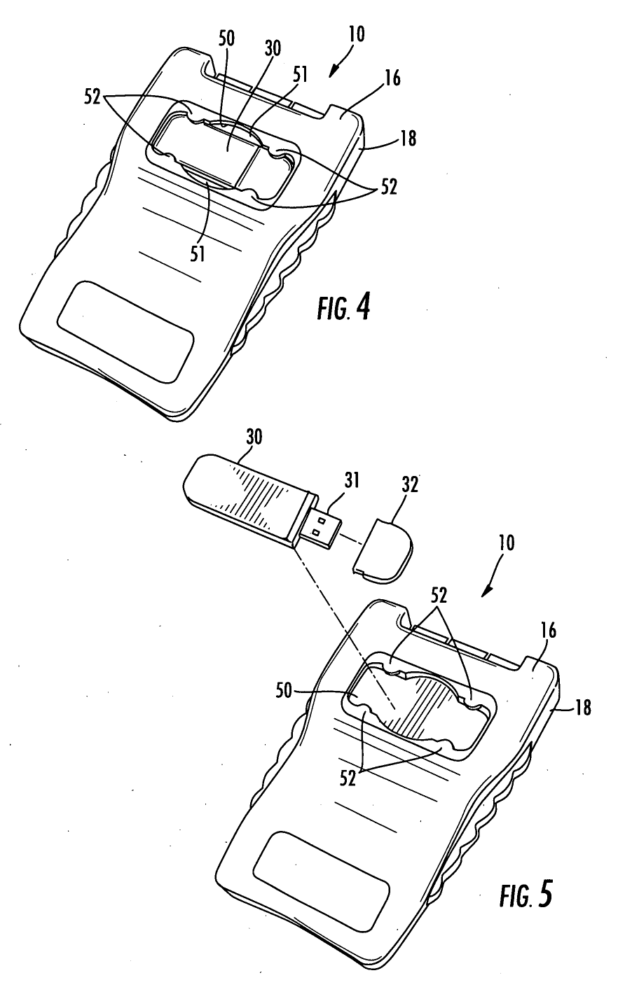

Referring back to FIG. 1, the illustrated electronic device 10 also includes a slot 40 in one of the connecting surfaces 18. One or more substrates 42 are slidably secured within the housing 12 and are configured to move between a stored position (FIG. 4) within the housing and an exposed position extending outwardly from the housing through the slot (FIG. 1). In the illustrated embodiment, three substrates 42 are slidably secured within the housing 12. However, any number of substrates may be utilized, and substrates with any configuration and shape may be utilized, without limitation. Each substrate 42 includes printed indicia 44 on at least one side thereof. The printed indicia 44 on a substrate 42 may relate to the function of the electronic device. For example, if the electronic device 10 is a body mass index (BMI) calculator, the printed indicia may relate to BMI information and/or other health information, etc. If the electronic device is a financial calculator, printed indicia on the substrate 42 may be financial in nature, etc.

The term “printed indicia” includes all types of printed material including, but not limited to, text, lettering (i.e., alphabetical characters, alphanumeric characters), designs, characters, logos, images, graphics, symbols, etc. Moreover, printed indicia may be utilized virtually anywhere on the substrate 42. Embodiments of the present invention are not limited to the illustrated location and configuration of either the substrates 42 or the printed indicia 44 thereon.

Referring to FIGS. 4-5, other embodiments of the present invention are illustrated. The illustrated electronic device 10 includes a storage compartment 50 for a memory device 30 in the bottom surface 16 thereof. The storage compartment 50 is configured to removably receive a memory device 30 therein. In the illustrated embodiment, the memory device 30 is substantially flush with the bottom surface 16. However, it is not required that memory device 30 be flush with the bottom surface. From a practical standpoint, a flush configuration or configuration wherein the memory device 30 is recessed within the storage compartment 24 may be desirable, the illustrated storage compartment has enlarged portions 51 that allow a user to insert his/her fingers therein to grasp a memory device stored therein.

The illustrated storage compartment 50 includes a plurality of tabs 52 that are configured to removably secure a memory device 30 within the storage compartment 50. The tabs 52 are resilient and/or are otherwise configured to allow a user to easily insert a memory device 30 within the storage compartment 50 and to easily remove the memory device 30 from the storage compartment 50 (e.g., a snug, sap-in fit, etc.). The illustrated memory device 30 is a USB flash device with USB connector 31 and a protective cap 32 covering the USB connector 31. Storage of the memory device 30 with the cover 32 overlying the USB connector further illustrates that the memory device 30 does not communicate in any way with the electronic device 10.

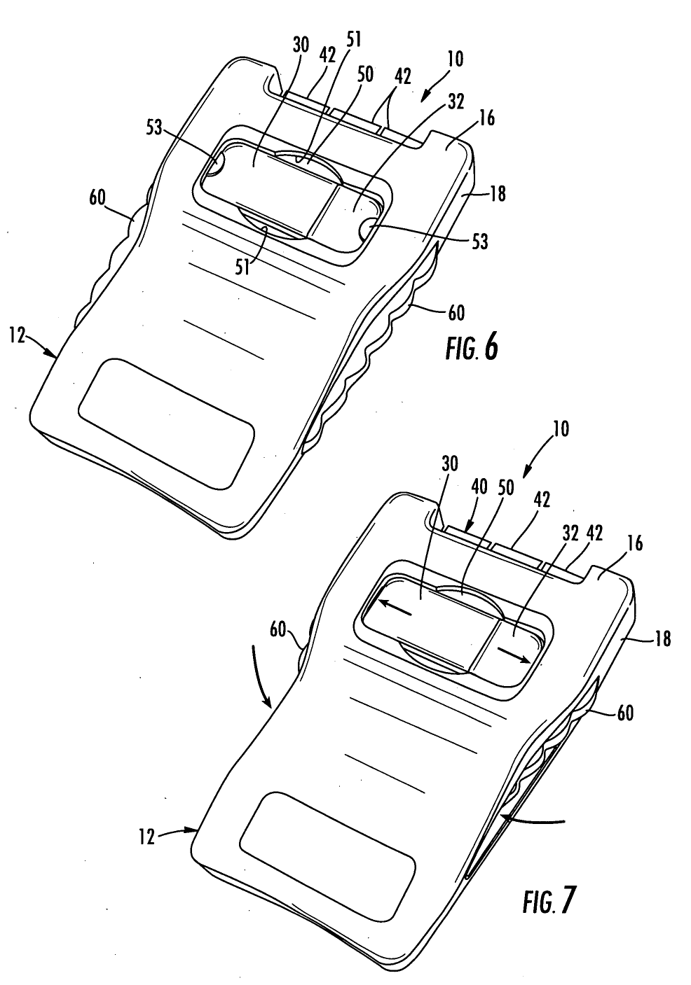

Referring to FIGS. 6-8, other embodiments of the present invention are illustrated. The illustrated electronic device 10 includes a storage compartment 50 for a memory device 30 in the bottom surface 16 thereof. The storage compartment 50 is configured to removably receive a memory device 30 therein. In the illustrated embodiment, the memory device 30 is substantially flush with the bottom surface 16. However, it is not required that memory device 30 be flush with the bottom surface. From a practical standpoint, a flush configuration or configuration wherein the memory device 30 is recessed within the storage compartment 24 may be desirable. The illustrated storage compartment has enlarged portions 51 that allow a user to insert his/her fingers therein to grasp a memory device stored therein.

The illustrated storage compartment 50 includes a pair of spring-actuated latches 53 that are configured to removably secure a memory device 30 within the storage compartment 50. The present invention is not, however, limited to the illustrated embodiment. A single spring-actuated latch may be utilized that would allow a memory device to be inserted and removed from the storage compartment 50.

The illustrated electronic device 10 includes respective finger grip portions 60 located on opposite connecting surfaces 18. The finger grip portions 60 are pivotally connected to the housing via pivot pin 62 and are operably connected at one end thereof to the spring-actuated latches 53, as illustrated. Accordingly, when a user squeezes the hand grip portions 60, the hand grip portions 60 pivot about pivot pin 62, thereby causing the spring-actuated latches to retract into the housing enabling removal of the memory device from the storage compartment 50.

When the finger grip portions 60 are released, the latches 53 return to a latched position (FIG. 6) and the finger grip portions 60 return to the position illustrated in FIG. 6. FIG. 7 shows the finger grips being squeezed and the latches 53 in a release position that allows the memory device 30 to be removed from the storage compartment 50.

In other embodiments, an ejector mechanism may be operably connected with the grip portions 60. Accordingly, when a user squeezes the hand grip portions 60, the hand grip portions 60 also activate an ejector mechanism to push the memory device 30 out of the storage compartment 50.

Embodiments of the present invention are not limited to the illustrated way that the finger grips 60 are connected to the spring-actuated latches. Various other ways of connecting the finger grip portions 60 to a spring-actuated latch may be utilized, without limitation. In some embodiments, the finger grip portions 60 are formed from a resilient, deformable material that facilitates handling of the electronic device 10 by a user. Moreover, the finger grip portions 60 can be effective in preventing slippage of a user's fingers during operation of the electronic device 10. The finger grip portions 60 may have various shapes and configurations and may be formed from various materials, without limitation.

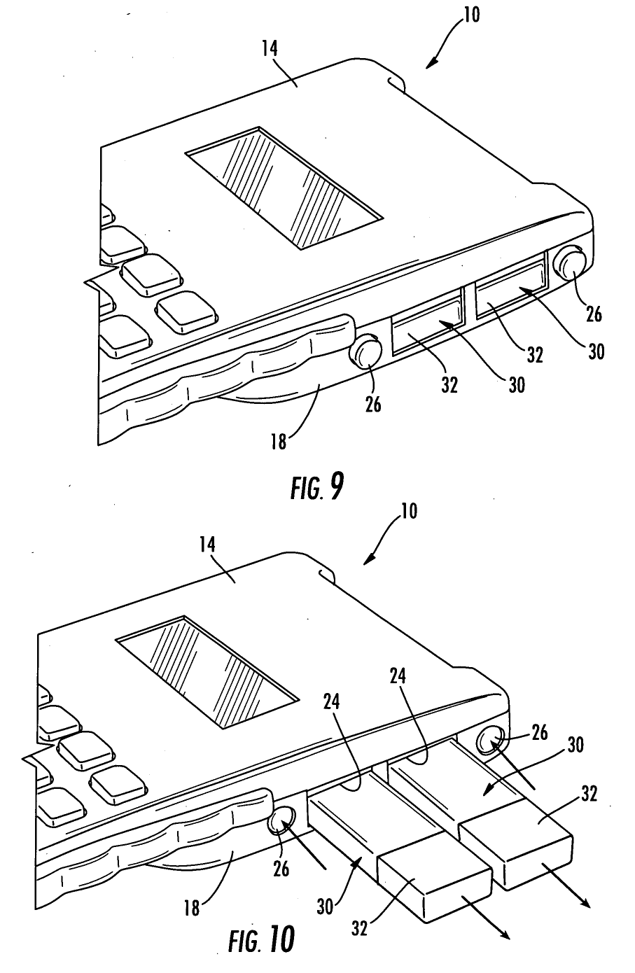

Referring to FIGS. 9-10, an electronic device 10 is illustrated with two, adjacent storage compartments 24 in a connecting surface 18 of the housing 12. Each illustrated storage compartment 24 includes a respective ejector mechanism with an actuator 26 extending from the housing 12 that allows a user to eject a memory device 30 stored therewithin. Electronic devices, according to embodiments of the present invention may have virtually any number of storage compartments 24 and in various locations, without limitation.

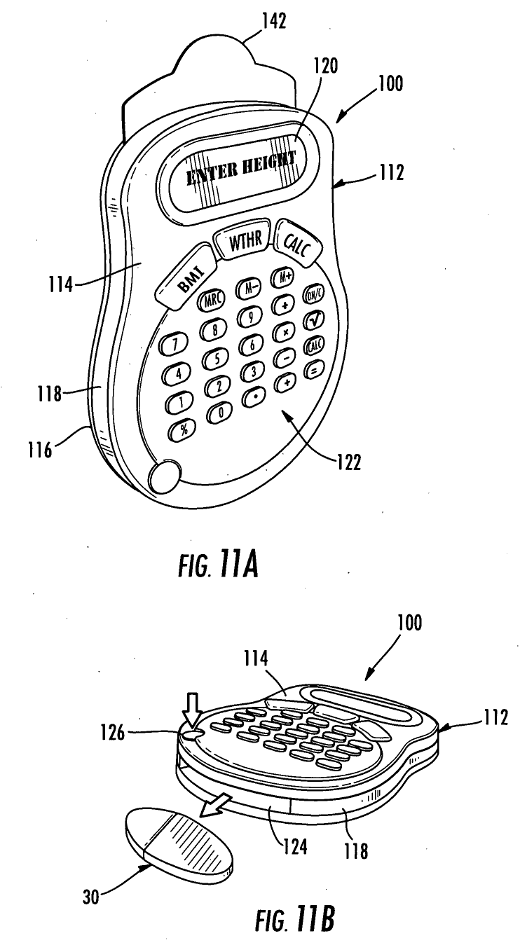

FIGS. 11A-11B, 12A-12B, 13A-13B, and 14A-14B illustrate other embodiments of the present invention. In FIGS. 11A-11B, a BMI calculator 100 that stores memory devices 30 in non-operative relationship therewith, according to embodiments of the present invention, is illustrated. The illustrated BMI calculator 100 includes a housing 112 having a top surface 114, a bottom surface 116, and a plurality of connecting surfaces 118 that connect the top surface 114 to the bottom surface 116. The illustrated BMI calculator 100 includes a display 120 that is viewable through the top surface 114 of the housing 112. A processor (not shown) is located within the housing 112 and is configured to calculate and display, via the display 120, a BMI number in response to user entry of weight and height data via keypad 122. A power source (e.g., battery) is also located within the housing 112 to power the processor and display 120, as would be understood by those skilled in the art.

A storage compartment 124 is located in a connecting surface 118 of the illustrated housing 112 and is configured to removably receive a memory device 30 therein in non-operative relationship with the electronic device 10. In the illustrated embodiment, the storage compartment 124 includes an ejector mechanism operably coupled therewith that is configured to eject a memory device 30 from the storage compartment 124. An actuator 126 extends from the housing top surface 114 adjacent the storage compartment 124, as illustrated.

As described above, embodiments of the present invention are not limited to storage compartments with ejector mechanisms. In other embodiments of the present invention, a storage compartment may be configured to receive a memory device such that a friction fit is obtained to allow the memory device to be stored therein, but also to allow easy removal by a user. Accordingly, storage compartment 124 may be configured to receive the memory device 30 therein and to allow a user to grasp the memory device 30 and remove it from the storage compartment 124.

In the illustrated embodiment, the memory device 30 may be stored substantially flush with the connecting surface 118 of the housing 112. However, it is not required that memory device 30 be flush with the connecting surface 118. From a practical standpoint, a flush configuration or configuration wherein the memory device 30 is recessed within the storage compartment 124 may be desirable. The illustrated electronic device 100 also includes a substrate 142 with printed indicia thereon that is slidably received within the housing 112, as described above.

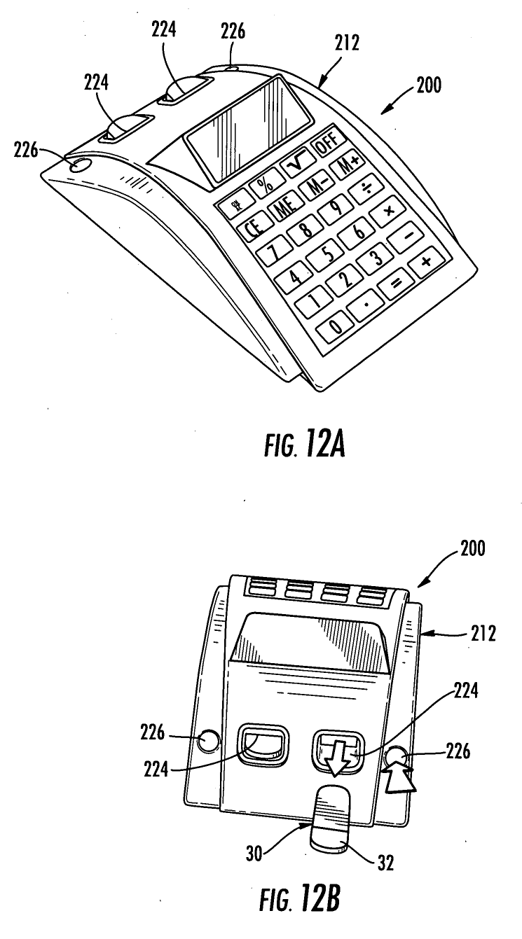

FIGS. 12A-12B illustrate an electronic device 200 that stores memory devices 30 in non-operative relationship therewith, according to other embodiments of the present invention. The illustrated electronic device 200 is a calculator with a pair of storage compartments 224 located in the housing 212. Each storage compartment 224 is configured to receive a respective memory device 30 therein. In the illustrated embodiment, each storage compartment 224 includes an ejector mechanism operably coupled therewith that is configured to eject a memory device 30 from the storage compartment 224. A respective actuator 226 extends from the housing 212 adjacent each storage compartment 224, as illustrated. When the actuator 226 is pressed by a user, the ejector mechanism ejects a memory device 30 from the storage compartment 224.

As described above, embodiments of the present invention are not limited to storage compartments with ejector mechanisms. In other embodiments of the present invention, a storage compartment may be configured to receive a memory device such that a friction fit is obtained to allow the memory device to be stored therein, but also to allow easy removal by a user. Accordingly, each storage compartment 224 may be configured to receive a memory device 30 therein and to allow a user to grasp the memory device 30 and remove it from the storage compartment 224.

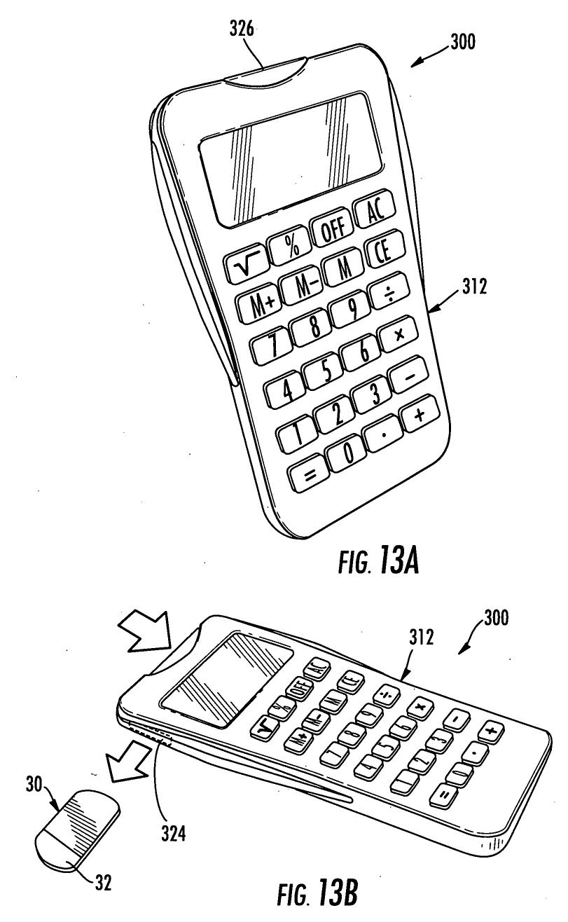

FIGS. 13A-13B illustrate an electronic device 300 that stores memory devices 30 in non-operative relationship therewith, according to other embodiments of the present invention. The illustrated electronic device 300 is a handheld calculator with a storage compartment 324 located in the housing 312. The storage compartment 324 is configured to receive a respective memory device 30 therein. The storage compartment 324 includes an ejector mechanism operably coupled therewith that is configured to eject a memory device 30 from the storage compartment 324. An actuator 326 extends from the housing 212, as illustrated. When the actuator 326 is pressed by a user, the ejector mechanism ejects a memory device 30 from the storage compartment 324.

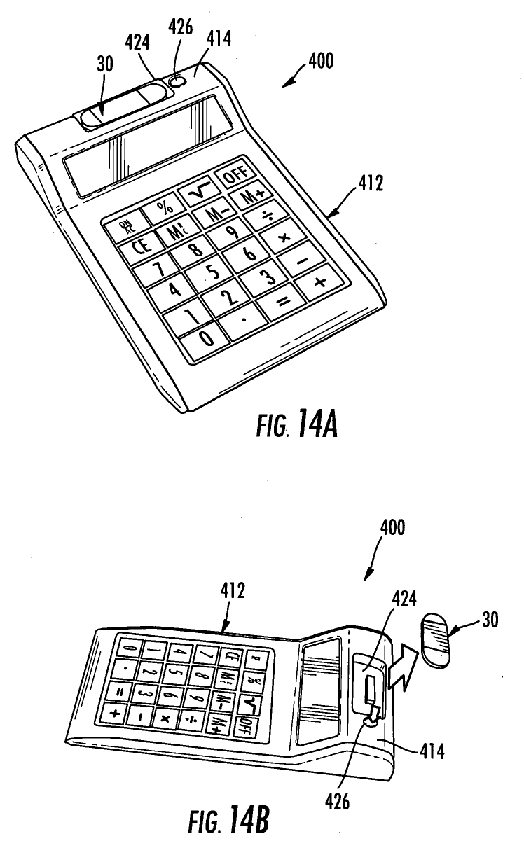

FIGS. 14A-14B illustrate an electronic device 400 that stores memory devices 30 in non-operative relationship therewith, according to other embodiments of the present invention. The illustrated electronic device 400 is a handheld calculator with a storage compartment 424 located in a top surface 414 of the housing 412. In the illustrated embodiment, the storage compartment 424 includes an ejector mechanism operably coupled therewith that is configured to eject a memory device 30 from the storage compartment 424. An actuator 426 extends from the housing top surface 414 adjacent the storage compartment 424, as illustrated.

As described above, embodiments of the present invention are not limited to storage compartments with ejector mechanisms. In other embodiments of the present invention, a storage compartment may be configured to receive a memory device such that a friction fit is obtained to allow the memory device to be stored therein, but also to allow easy removal by a user. Accordingly, storage compartment 424 may be configured to receive the memory device 30 therein and to allow a user to grasp the memory device 30 and remove it from the storage compartment 424.

In the illustrated embodiment, the memory device 30 may be stored substantially flush with the top surface 414 of the housing 412. However, it is not required that memory device 30 be flush with the top surface 414. From a practical standpoint, a flush configuration or configuration wherein the memory device 30 is recessed within the storage compartment 424 may be desirable.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed:

1. An electronic device, comprising:
a housing having a top surface, a bottom surface, and a plurality of connecting surfaces that connect the top surface to the bottom surface;
a display mounted within the top surface;
a keypad mounted within the top surface adjacent the display; and
a storage compartment in one of the housing surfaces that is configured to removably receive a memory device therein in non-operative relationship with the electronic device.

2. The device of claim 1, wherein the storage compartment is configured to removably receive the memory device entirely therewithin such that no portion of the memory device extends from the housing.

3. The device of claim 1, wherein the storage compartment is located in a connecting surface and is configured to removably receive a memory device therein such that the memory device is substantially flush with the connecting surface.

4. The device of claim 1, wherein the storage compartment is located in the top surface and is configured to removably receive a memory device therein such that the memory device is substantially flush with the top surface.

5. The device of claim 1, wherein the storage compartment is located in the bottom surface and is configured to removably receive a memory device therein such that the memory device is substantially flush with the bottom surface.

6. The device of claim 1, wherein the storage compartment comprises a spring-actuated latch configured to removably secure a memory device within the storage compartment.

7. The device of claim 1, further comprising an ejector mechanism operably coupled with the storage compartment that is configured to eject a memory device from the storage compartment when activated by a user.

8. The device of claim 7, wherein the ejector mechanism comprises an actuator extending from a housing surface, and wherein the actuator causes the ejector mechanism to eject a memory device when activated by a user.

9. The device of claim 1, wherein opposite connecting surfaces comprise respective finger grip portions of resilient, deformable material.

10. The device of claim 1, wherein opposite connecting surfaces comprise respective finger grip portions, and further comprising an ejector mechanism operably coupled with the storage compartment that is configured to eject a memory device from the storage compartment, and wherein the finger grip portions are operatively connected with the ejector mechanism and cause the ejector mechanism to eject a memory device from the storage compartment when squeezed by a user.

11. The device of claim 1, further comprising a plurality of storage compartments in one or more of the housing surfaces, wherein each storage compartment is configured to removably receive a respective memory device therein in non-operative relationship with the electronic device.

12. The device of claim 1, further comprising a processor that performs and displays math computations, via the display, in response to user entry via the keypad.

13. The device of claim 12, wherein the processor calculates and displays, via the display, a body mass index number in response to user entry of weight and height data via the keypad.

14. The device of claim 1, wherein the housing comprises a slot in one of the surfaces, and further comprising at least one substrate slidably secured within the housing and configured to move between a stored position within the housing and an exposed position extending outwardly from the housing through the slot, each substrate having printed indicia on a side thereof.

15. An electronic device, comprising:
a housing having a top surface, a bottom surface, and a plurality of connecting surfaces that connect the top surface to the bottom surface;
a display mounted within the top surface;
a keypad mounted within the top surface adjacent the display;
a storage compartment in one of the housing surfaces that is configured to removably receive a memory device therein in non-operative relationship with the electronic device and such that no portion of the memory device extends from the housing; and
an ejector mechanism operably coupled with the storage compartment that is configured to eject a memory device from the storage compartment when activated by a user.

16. The device of claim 15, wherein the storage compartment is located in a connecting surface and is configured to removably receive a memory device therein such that the memory device is substantially flush with the connecting surface.

17. The device of claim 15, wherein the storage compartment is located in the top surface and is configured to removably receive a memory device therein such that the memory device is substantially flush with the top surface.

18. The device of claim 15, wherein the storage compartment is located in the bottom surface and is configured to removably receive a memory device therein such that the memory device is substantially flush with the bottom surface.

19. The device of claim 15, wherein the storage compartment comprises a spring-actuated latch configured to removably secure a memory device within the storage compartment.

20. The device of claim 15, wherein the ejector mechanism comprises an actuator extending from a housing surface, and wherein the actuator causes the ejector mechanism to eject a memory device when activated by a user.

21. The device of claim 15, wherein opposite connecting surfaces comprise respective finger grip portions of resilient, deformable material.

22. The device of claim 15, wherein opposite connecting surfaces comprise respective finger grip portions, and further comprising an ejector mechanism operably coupled with the storage compartment that is configured to eject a memory device from the storage compartment, and wherein the finger grip portions are operatively connected with the ejector mechanism and cause the ejector mechanism to eject a memory device from the storage compartment when squeezed by a user.

23. The device of claim 15, further comprising a plurality of storage compartments in one or more of the housing surfaces, wherein each storage compartment is configured to removably receive a respective memory device therein in non-operative relationship with the electronic device.

24. The device of claim 15, further comprising a processor that performs and displays math computations, via the display, in response to user entry via the keypad.

25. The device of claim 24, wherein the processor calculates and displays, via the display, a body mass index number in response to user entry of weight and height data via the keypad.

26. The device of claim 15, wherein the housing comprises a slot in one of the surfaces, and further comprising at least one substrate slidably secured within the housing and configured to move between a stored position within the housing and an exposed position extending outwardly from the housing through the slot, each substrate having printed indicia on a side thereof.

27. A combination electronic device and memory device, comprising:
a housing having a top surface, a bottom surface, and a plurality of connecting surfaces that connect the top surface to the bottom surface;
a display mounted within a housing surface;
a keypad mounted within a housing surface;
a storage compartment in one of the housing surfaces; and
a memory device removably stored within the storage compartment in non-operative relationship with the electronic device.

28. The combination electronic device and memory device of claim 27, wherein the memory device stored within the storage compartment has a USB connector and a protective cap covering the USB connector.

29. The combination electronic device and memory device of claim 27, wherein the memory device is stored entirely within the storage compartment such that no portion of the memory device extends from the housing.

30. The combination electronic device and memory device of claim 27, wherein the storage compartment is located in a connecting surface, and wherein the memory device is stored therein so as to be substantially flush with the connecting surface.

31. The combination electronic device and memory device of claim 27, wherein the storage compartment is located in the top surface, and wherein the memory device is stored therein so as to be substantially flush with the top surface.

32. The combination electronic device and memory device of claim 27, wherein the storage compartment is located in the bottom surface, and wherein the memory device is stored therein so as to be substantially flush with the bottom surface.

33. The combination electronic device and memory device of claim 27, wherein the storage compartment comprises a spring-actuated latch.

34. The combination electronic device and memory device of claim 27, further comprising an ejector mechanism operably coupled with the storage compartment that is configured to eject the memory device from the storage compartment when activated by a user.

35. The combination electronic device and memory device of claim 34, wherein the ejector mechanism comprises an actuator extending from a housing surface, and wherein the actuator causes the ejector mechanism to eject the memory device when activated by a user.

36. The combination electronic device and memory device of claim 27, wherein opposite connecting surfaces comprise respective finger grip portions of resilient, deformable material.

37. The combination electronic device and memory device of claim 27, wherein opposite connecting surfaces comprise respective finger grip portions, and further comprising an ejector mechanism operably coupled with the storage compartment that is configured to eject the memory device from the storage compartment when activated by a user, and wherein the finger grip portions are operatively connected with the ejector mechanism and cause the ejector mechanism to eject the memory device from the storage compartment when squeezed by a user.

38. The combination electronic device and memory device of claim 27, further comprising a processor that performs and displays math computations, via the display, in response to user entry via the keypad.

39. The combination electronic device and memory device of claim 38, wherein the processor calculates and displays, via the display, a body mass index number in response to user entry of weight and height data via the keypad.

40. The combination electronic device and memory device of claim 27, wherein the housing comprises a slot in one of the surfaces, and further comprising at least one substrate slidably secured within the housing and configured to move between a stored position within the housing and an exposed position extending outwardly from the housing through the slot, each substrate having printed indicia on a side thereof.
